(19) United States
(12) Patent Application Publication
(10) Pub. No.: US 2010/0078699 A1
(43) Pub. Date: Apr. 1, 2010

(54) NONVOLATILE SEMICONDUCTOR STORAGE DEVICE

(75) Inventor: Hiroaki Nakano, Kanagawa (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/500,024

(22) Filed: Jul. 9, 2009

(30) Foreign Application Priority Data
Oct. 1, 2008 (JP) 2008-256516

(51) Int. Cl. H01L 29/94

(52) U.S. Cl. 257/298; 257/E29.345

(57) ABSTRACT

A silicide layer is formed at least in a part on an impurity diffusing layer to avoid a region on a gate electrode on a gate oxide film. Voltage is applied between the gate electrode and the impurity diffusing layer to destroy the gate oxide film.

### CROSS-REFERENCE TO RELATED APPLICATIONS

This application is based upon and claims the benefit of priority from the prior Japanese Patent Application No. 2008-256516, filed on Oct. 1, 2008; the entire contents of which are incorporated herein by reference.

### BACKGROUND OF THE INVENTION

1. Field of the Invention

The present invention relates to a nonvolatile semiconductor storage device, and more particularly, is suitably applied to a semiconductor storage device of an insulating film destruction type that is writable only once by destroying a gate insulating film of a metal oxide semiconductor (MOS) transistor.

2. Description of the Related Art

In some nonvolatile semiconductor storage device that is writable only once, a MOS transistor is used as a fuse element (H. Ito et. al., “Pure CMOS One-time Programmable Memory using Gate-Ox Anti-Fuse”, Proceedings of the IEEE 2004 Custom Integrated Circuits Conference, pp. 469-472). In this nonvolatile semiconductor storage device, when information is stored in the fuse element, high voltage exceeding maximum rating is applied to the fuse element of the MOS structure and an insulating film is destroyed. Information “0” is stored in the fuse element before the insulating film destruction. Information “1” is stored in the fuse element after the insulating film destruction.

As applications of such a nonvolatile semiconductor storage device, the nonvolatile semiconductor storage device is used for storing, for example, defective element remedy information for semiconductor storage devices such as a dynamic random access memory (DRAM), a static random access memory (SRAM), and an electrically erasable and programmable read only memory (EEPROM), information for setting states of various circuits that configure an large scale integration (LSI), and identification information for chips.

In such applications, it is required that the fuse element is programmed at a stage of a test in a manufacturing process and a state of the fuse element is maintained for a long period after shipment of a product. Depending on manufacturing conditions and program conditions for the fuse element, it is not entirely unlikely that data is destroyed because of aged deterioration after the programming. Therefore, a request concerning reliability of the fuse element is strict. As a way of using the fuse element on the product, the fuse element is often used to substantially automatically read out data stored therein when a power supply is turned on and transfer the data to the circuits. When the fuse element is defective, remedy is extremely difficult and, when even only one bit is defective, the defect could be fatal to the product. The yield of the fuse element is likely to directly lead to the yield of the product. When a fuse element that stores information by destroying a gate oxide film is used, the gate oxide film is reduced in thickness according to the progress of refining of a design rule. Therefore, in particular, maintenance of reliability is strict. As such a fuse element, a MOS transistor is typically used. Silicide is formed on the surfaces of gate, source, and drain regions for the purpose of reducing resistance.

However, when the MOS transistor is used as the fuse element, depending on a program condition in destroying the gate oxide film, metal atoms forming the silicide are likely to intrude into the gate oxide film because of electromigration. When such a phenomenon occurs, the resistance of a current path of the fuse element depends on a state of the metal atoms. When the state of the metal atoms is affected by thermal stress or current stress in a reliability test, the resistance of the fuse element fluctuates and, in a worse case, a readout error is likely to occur.

### BRIEF SUMMARY OF THE INVENTION

A nonvolatile semiconductor storage device according to an embodiment of the present invention comprises: a gate electrode formed on a semiconductor substrate via a gate oxide film; an impurity diffusing layer formed on the semiconductor substrate to be aligned at least on one side of the gate electrode; a silicide layer formed in at least a part on the impurity diffusing layer to avoid a region on the gate electrode on the gate oxide film; and a logic circuit configured to destroy the gate oxide film by applying voltage between the gate electrode and the impurity diffusing layer.

A nonvolatile semiconductor storage device according to an embodiment of the present invention comprises: a fuse element including a MOS transistor; an internal-potential generating circuit that applies voltage between a gate electrode and an impurity diffusing layer of the MOS transistor to destroy a gate oxide film of the MOS transistor; a sense amplifier that reads out data stored in the fuse element; a barrier transistor that protects the sense amplifier from the voltage for destroying the gate oxide film; and a selection transistor that selects the fuse element in which the gate oxide film of the MOS transistor is destroyed, wherein a silicide layer is formed on gate electrodes and impurity diffusing layers of the barrier transistor and the selection transistor and is not formed on the gate electrode and the impurity diffusing layer of the MOS transistor.

A nonvolatile semiconductor storage device according to an embodiment of the present invention comprises: a fuse element including a capacitor; an internal-potential generating circuit that applies voltage between capacitor electrodes of the capacitor to destroy a capacitor insulating film of the capacitor; a sense amplifier that reads out data stored in the fuse element; a barrier transistor that protects the sense amplifier from the voltage for destroying the capacitor insulating film; and a selection transistor that selects the fuse element in which the capacitor insulating film of the capacitor is destroyed, wherein a silicide layer is formed on gate electrodes and impurity diffusing layers of the barrier transistor and the selection transistor and is not formed on the capacitor electrodes of the capacitor.

### BRIEF DESCRIPTION OF THE DRAWINGS

FIG. 1 is a block diagram of a schematic configuration of a nonvolatile semiconductor storage device according to a first embodiment of the present invention;

FIG. 2 is a block diagram of a schematic configuration of a fuse macro block configured by using the nonvolatile semiconductor storage device shown in FIG. 1;

FIG. 3A is a sectional view of a schematic configuration of a MOS transistor used in a barrier transistor 12, a selection transistor 13, a sense amplifier 14, a fuse data register 15, a program control register 16, a control logic 17, and a selector 18 shown in FIG. 1;

FIG. 3B is a plan view of the schematic configuration of the MOS transistor used in the barrier transistor 12, the selection transistor 13, the sense amplifier 14, the fuse data register 15, the program control register 16, the control logic 17, and the selector 18 shown in FIG. 1;

FIG. 4A is a sectional view of a schematic configuration of a fuse element 11 used in the nonvolatile semiconductor storage device shown in FIG. 1;

FIG. 4B is a plan view of the schematic configuration of the fuse element 11 used in the nonvolatile semiconductor storage device shown in FIG. 1;

FIG. 5A is a sectional view of a schematic configuration of a fuse element used in a nonvolatile semiconductor storage device according to a second embodiment of the present invention;

FIG. 5B is a plan view of the schematic configuration of the fuse element used in the nonvolatile semiconductor storage device according to the second embodiment;

FIG. 6 is a block diagram of a schematic configuration of a nonvolatile semiconductor storage device according to a third embodiment of the present invention;

FIG. 7A is a sectional view of a schematic configuration of a fuse element 19 used in the nonvolatile semiconductor storage device shown in FIG. 6;

FIG. 7B is a plan view of the schematic configuration of the fuse element 19 used in the nonvolatile semiconductor storage device shown in FIG. 6;

FIG. 8A is a sectional view of a schematic configuration of a fuse element used in a nonvolatile semiconductor storage device according to a fourth embodiment of the present invention;

FIG. 8B is a plan view of the schematic configuration of the fuse element used in the nonvolatile semiconductor storage device according to the fourth embodiment;

FIG. 9A is a sectional view of a schematic configuration of a fuse element used in a nonvolatile semiconductor storage device according to a fifth embodiment of the present invention;

FIG. 9B is a plan view of the schematic configuration of the fuse element used in the nonvolatile semiconductor storage device according to the fifth embodiment;

FIG. 10A is a sectional view of a schematic configuration of a fuse element used in a nonvolatile semiconductor storage device according to a sixth embodiment of the present invention; and

FIG. 10B is a plan view of the schematic configuration of the fuse element used in the nonvolatile semiconductor storage device according to the sixth embodiment.

### DETAILED DESCRIPTION OF THE INVENTION

Exemplary embodiments of the present invention are explained in detail below with reference to the accompanying drawings. The present invention is not limited by the embodiments.

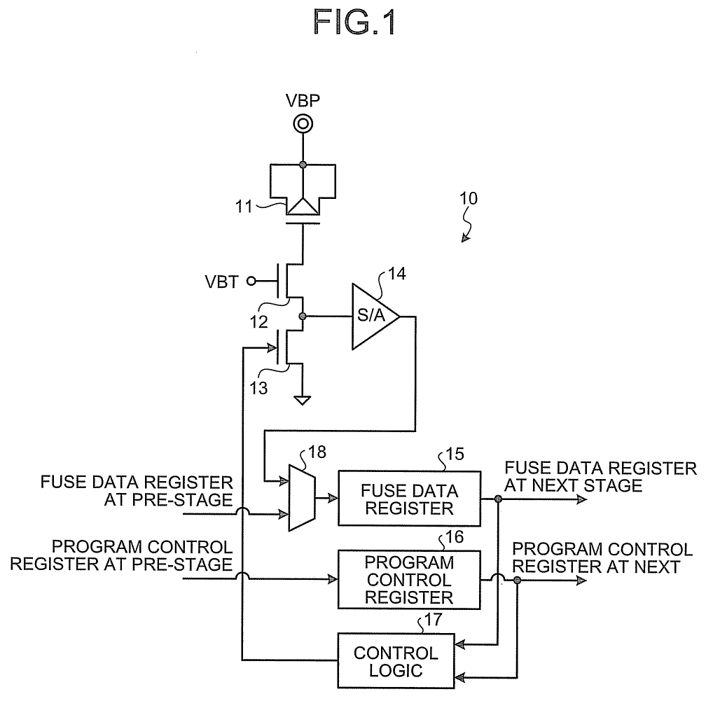

FIG. 1 is a block diagram of a schematic configuration of a nonvolatile semiconductor storage device according to a first embodiment of the present invention.

In FIG. 1, a nonvolatile semiconductor storage device 10 includes a fuse element 11, a barrier transistor 12, a selection transistor 13, a sense amplifier 14, a fuse data register 15, a program control register 16, a control logic 17, and a selector 18. The fuse element 11 can be configured by using a MOS transistor. A source, a drain, and a well of the MOS transistor are connected in common. The barrier transistor 12 can protect the sense amplifier 14 from voltage for destroying a gate oxide film of the fuse element 11. The selection transistor 13 can select the fuse element 11 in which the gate oxide film of the MOS transistor is destroyed. The sense amplifier 14 can read out data stored in the fuse element 11. The fuse data register 15 can store the data read out from the fuse element 11. The program control register 16 can store program control information for performing control during programming. The control logic 17 can control the operation of the selection transistor 13 during the programming. The selector 18 can select the data of the fuse element 11 read out by the sense amplifier 14 or data stored in a fuse data register of the pre-stage and output the selected data to the fuse data register 15 of the own stage of the selector 18.

In a MOS transistor used in the barrier transistor 12, the selection transistor 13, the sense amplifier 14, the fuse data register 15, the program control register 16, the control logic 17, and the selector 18, in order to reduce contact resistance and the like, a silicide layer can be formed on a gate electrode and an impurity diffusing layer of the MOS transistor. A silicide layer can be prevented from being formed on a gate electrode and an impurity diffusing layer of the MOS transistor of the fuse element 11. Alternatively, a silicide layer can be formed at least in a part on the impurity diffusing layer to avoid a region on the gate electrode on the gate oxide film of the MOS transistor of the fuse element 11.

A gate of the MOS transistor of the fuse element 11 is connected to a drain of the barrier transistor 12. A source of the barrier transistor 12 is connected to a drain of the selection transistor 13 and an input terminal of the sense amplifier 14. An output terminal of the sense amplifier 14 is connected to one input terminal of the selector 18. The other input terminal of the selector 18 is connected to an output terminal of the fuse data register of the pre-stage. An output terminal of the selector 18 is connected to an input terminal of the fuse data register 15. An output terminal of the fuse data register 15 is connected to an input terminal of a fuse data register of the next stage and one input terminal of the control logic 17. An input terminal of the program control register 16 is connected to a program control register of the pre-stage. An output terminal of the program control register 16 is connected to an input terminal of the program control register of the pre-stage and the other input terminal of the control logic 17. An output terminal of the control logic 17 is connected to a gate of the selection transistor 13.

Before the gate oxide film of the MOS transistor of the fuse element 11 is destroyed, data ‘0’ is stored in the fuse element 11. When data ‘1’ is written in the fuse element 11, program control information is transferred to the program control register 16 of the own stage via a program control register serially connected to the program control register 16.

Program voltage VBP is applied to a substrate side of the fuse element 11. Barrier voltage VBT is applied to a gate of the barrier transistor 12. A gate side of the fuse element 11 is charged in advance to potential not so high as to destroy the gate oxide film of the MOS transistor of the fuse element 11.

The control logic 17 determines, based on the data of the fuse element 11 stored in the fuse data register 15 and the program control information stored in the program control register 16, timing for performing programming operation. In performing the programming, the control logic 17 sets the potential at the gate of the selection transistor 13 to a high level and turns on the selection transistor 13 to reduce the potential at the gate of the fuse element 11 to low potential VSS. As a result, high voltage enough for destroying the gate oxide film is applied to the gate oxide film of the MOS transistor of the fuse element 11 and the gate oxide film is destroyed. As a result, data ‘1’ is written in the fuse element 11.

When the data ‘1’ is written in the fuse element 11, the control logic 17 turns off the selection transistor 13 and stops the high voltage from being applied to the fuse element 11.

In reading out the data from the fuse element 1, the program voltage VBP and the barrier voltage VBT are set to voltages suitable for the readout. For example, the program voltage VBP is set to power supply voltage VDD. The barrier voltage VBT is set to voltage about twice as high as the power supply voltage VDD. The input terminal of the sense amplifier 14 is once discharged to set the potential to the low potential VSS and is then put on standby for fixed time. During this time, when the data ‘0’ is written in the fuse element 11, the potential at the input terminal of the sense amplifier 14 is maintained at the low potential VSS. On the other hand, when the data ‘1’ is written in the fuse element 11, electric charges are charged in the input terminal of the sense amplifier 14 via the destroyed gate oxide film of the fuse element 11. The potential at the input terminal of the sense amplifier 14 rises. The sense amplifier 14 determines, according to a potential difference between the potentials, whether the data of the fuse element 11 is ‘0’ or ‘1’ and latches the data to the sense amplifier 11 itself.

The data latched to the sense amplifier 14 is transferred to the fuse data register 15 and transferred to the outside via a serially-connected register chain.

A fuse macro block is configured by serially connecting a plurality of stages of such nonvolatile semiconductor storage devices 10.

A silicide layer is prevented from being formed on the gate electrode and the impurity diffusing layer of the MOS transistor of the fuse element 11. This makes it possible to suppress metal atoms included in the silicide layer from intruding into the gate oxide film even when high voltage is applied to the gate oxide film of the MOS transistor of the fuse element 11 via the gate electrode during the programming. Therefore, it is possible to suppress the resistance of a current path of the fuse element 11 from fluctuating according to a state of the metal atoms included in the silicide layer. It is possible to prevent a readout error from occurring even when the fuse element 11 is affected by thermal stress and current stress in a reliability test.

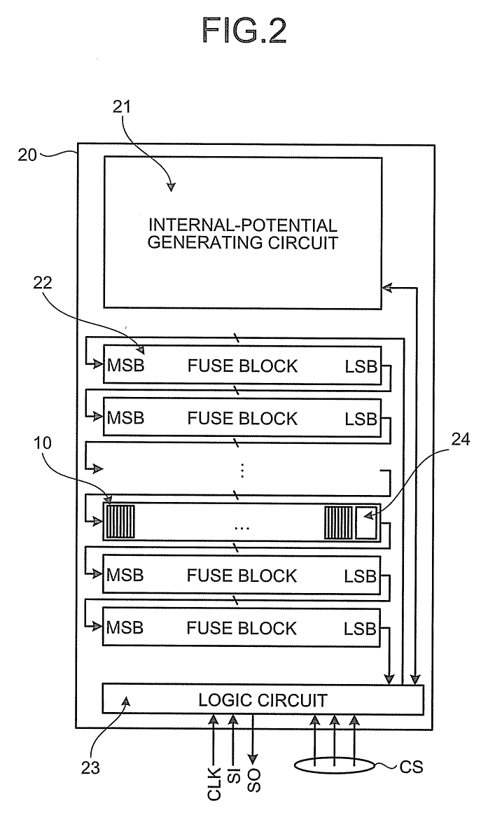

FIG. 2 is a block diagram of a schematic configuration of the fuse macro block configured by using the nonvolatile semiconductor storage device shown in FIG. 1.

In FIG. 2, a fuse macro block 20 includes an internal-potential generating circuit 21, a fuse block 22, and a logic circuit 23. The fuse block 22 includes the nonvolatile semiconductor storage device 10 and a control logic 24.

The internal-potential generating circuit 21 can generate the program voltage VBP applied to the fuse element 11 shown in FIG. 1 and the barrier voltage VBT applied to the barrier transistor 1 shown in FIG. 1. The fuse block 22 is configured by serially connecting a plurality of the nonvolatile semiconductor storage devices 10 shown in FIG. 1. The control logic 24 that controls these nonvolatile semiconductor storage devices 10 is provided. The fuse block 22 is configured by, for example, serially connecting the nonvolatile semiconductor storage devices 10 for 64 bits. A register chain of 64×16=1024 bits can be configured by, for example, serially connecting sixteen stages of the fuse blocks 22.

The logic circuit 23 can serially input programming data to the fuse blocks 22 in synchronization with a clock signal CLK and serially output data SO read out from the fuse blocks 22. The logic circuit 23 can perform, based on a control signal CS, control of writing and readout of the nonvolatile semiconductor storage device 10.

In such a fuse macro block 20, the sense amplifier 14 and the control logic 17 shown in FIG. 1 are provided for each of the nonvolatile semiconductor storage devices 10. Therefore, it is possible to facilitate design of a storage device that stably operates under broad conditions.

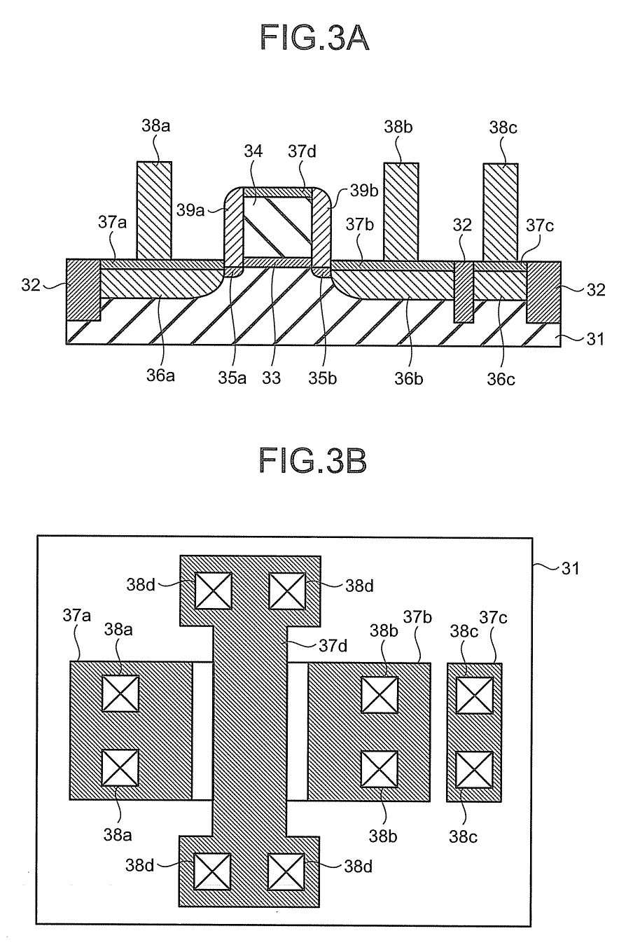

FIGS. 3A and 3B are a sectional view and a plan view of a schematic configuration of the MOS transistor used in the barrier transistor 12, the selection transistor 13, the sense amplifier 14, the fuse data register 15, the program control register 16, the control logic 17, and the selector 18 shown in FIG. 1.

In FIGS. 3A and 3B, device isolation regions 32 are formed in a semiconductor substrate 31 in which a well is formed. A material of the semiconductor substrate 31 is not limited to Si and can be selected out of, for example, Ge, SiGe, SiC, SiSn, PbS, GaAs, InP, GaP, GaN, AnSe, and GaInAsP. An STI structure or a LOCOS structure can be used for the device isolation regions 32.

In an active region on the semiconductor substrate 31 isolated by the device isolation regions 32, a gate electrode 34 is formed via a gate oxide film 33. Sidewalls 39a and 39b are formed on sides of the gate electrode 34. As a material of the gate electrode 34, for example, polysilicon can be used. As a material of the sidewalls 39a and 39b, for example, a silicon oxide film or a PSG film or a BPSG film can be used.

On both sides of a channel region formed in the semiconductor substrate 31 below the gate electrode 34, impurity diffusing layers 36a and 36b are formed via LDD layers 35a and 35b, respectively. Beside the impurity diffusing layer 36b, an impurity diffusing layer 36c is formed via the device isolation region 32. Silicide layers 37a to 37c are formed on the impurity diffusing layers 36a to 36c, respectively. A silicide layer 37d is formed on the gate electrode 34.

On the impurity diffusing layers 36a to 36c, contact electrodes 38a to 38c electrically connected to the impurity diffusing layers 36a to 36c via the silicide layers 37a to 37c, respectively, are formedy. On the gate electrode 34, contact electrodes 38d electrically connected to the gate electrode 34 via the silicide layer 37d are formed. The contact electrodes 38a to 38c can be electrically connected to one another.

A conduction type of the impurity diffusing layers 36a and 36b and a conduction type of the well formed in the semiconductor substrate 31 can be set different from each other. A conduction type of the impurity diffusing layer 36c and the conduction type of the well formed in the semiconductor substrate 31 can be set equal to each other. For example, the conduction type of the impurity diffusing layers 36a and 36b can be set to an N type and the conduction type of the impurity diffusing layer 36c and the well formed in the semiconductor substrate 31 can be set to a P type. Alternatively, the conduction type of the impurity diffusing layers 36a and 36b can be set to the P type and the conduction type of the impurity diffusing layer 36c and the well formed in the semiconductor substrate 31 can be set to the N type. As metal for silicide formation, for example, Ni, Co, W, Mo, and the like can be used.

In the MOS transistor used in the barrier transistor 12, the selection transistor 13, the sense amplifier 14, the fuse data register 15, the program control register 16, the control logic 17, and the selector 18 shown in FIG. 1, contact resistance and the like can be reduced by using the configuration shown in FIGS. 3A and 3B.

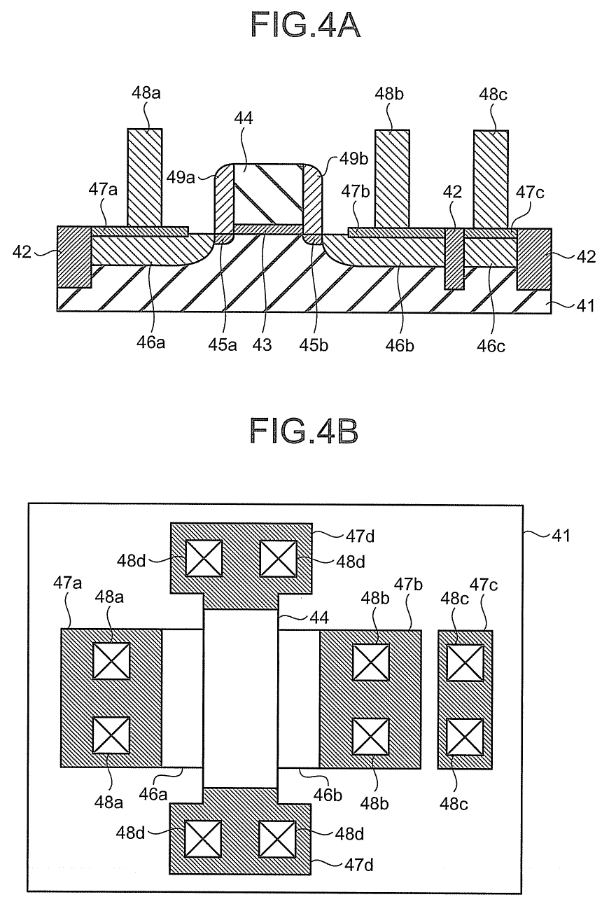

FIGS. 4A and 4B are a sectional view and a plan view of a schematic configuration of the fuse element 11 used in the nonvolatile semiconductor storage device shown in FIG. 1.

In FIGS. 4A and 4B, device isolation regions 42 are formed in a semiconductor substrate 41 in which a well is formed. In an active region on the semiconductor substrate 41 isolated by the device isolation regions 42, a gate electrode 44 is formed via a gate oxide film 43. Sidewalls 49a and 49b are formed on sides of the gate electrode 44.

On both sides of a channel region formed in the semiconductor substrate 41 below the gate electrode 44, impurity diffusing layers 46a and 46b are formed via LDD layers 45a and 45b, respectively. Beside the impurity diffusing layer 46b, an impurity diffusing layer 46c is formed via the device isolation region 42. Silicide layers 47a to 47c are formed on the impurity diffusing layers 46a to 46c, respectively. A silicide layer 47d is formed on the gate electrode 44.

The silicide layers 47a and 47b can be formed on the impurity diffusing layers 46a and 46b spacing from the sidewalls 49a and 49b, respectively. The silicide layer 47d can be formed in a contact region on the gate electrode 44 to avoid a region on the gate electrode 44 on the gate oxide film 43.

On the impurity diffusing layers 46a to 46c, contact electrodes 48a to 48c electrically connected to the impurity diffusing layers 46a to 46c via the silicide layers 47a to 47c, respectively, are formed. On the gate electrode 44, contact electrodes 48d electrically connected to the gate electrode 44 via the silicide layer 47d are formed. The contact electrodes 48a to 48c can be electrically connected to one another.

A conduction type of the impurity diffusing layers 46a and 46b can be set to the N type and a conduction type of the well formed in the semiconductor substrate 41 can be set to the P type. Alternatively, the conduction type of the impurity diffusing layers 46a and 46b can be set to the P type and the conduction type of the impurity diffusing layer 46c and the well formed in the semiconductor substrate 41 can be set to the N type.

When the configuration shown in FIGS. 4A and 4B are used as the MOS transistor of the fuse element 11 shown in FIG. 1, the program voltage VBP is applied to the impurity diffusing layers 46a to 46c in a state in which the potential of the gate electrode 44 is maintained at the low potential VSS. As a result, the gate oxide film 43 is destroyed.

In the MOS transistor of the fuse element 11 shown in FIG. 1, by using the configuration shown in FIGS. 4A and 4B, it is possible to suppress metal atoms included in the silicide layers 47a to 47d from intruding into the gate oxide film 43 while making it possible to reduce contact resistance. Further, it is possible to suppress the resistance of the current path of the fuse element 11 from fluctuating according to a state of the metal atoms included in the silicide layers 47a to 47d.

As a method of forming the silicide layers 47d in parts on the gate electrode 44 to avoid the region on the gate electrode 44 on the gate oxide film 43, for example, it is possible to selectively remove, after forming the silicide layer 37d shown in FIGS. 3A and 3B over the entire surface of the gate electrode 34, the silicide layer 37d on the gate electrode 34 on the gate oxide film 33 by etching. Alternatively, it is possible to form, before forming a metal film for silicide formation on the gate electrode 44, a silicide prevention film such as a silicon oxide film or a silicon nitride film on the gate electrode 44 on the gate oxide film 43 and then perform siliciding.

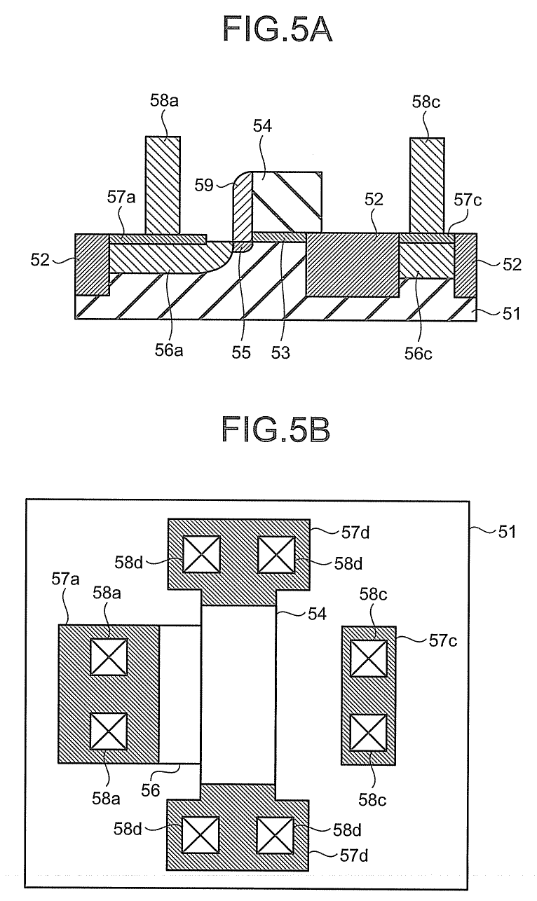

FIGS. 5A and 5B are a sectional view and a plan view of a schematic configuration of a fuse element used in a nonvolatile semiconductor storage device according to a second embodiment of the present invention.

In FIGS. 5A and 5B, device isolation regions 52 are formed in a semiconductor substrate 51 in which a well is formed. In an active region on the semiconductor substrate 51 isolated by the device isolation regions 52, a gate electrode 54 is formed via a gate oxide film 53. A sidewall 59 is formed on one side of the gate electrode 54. The other side of the gate electrode 54 is aligned to extend over the device isolation region 52.

On one side of a channel region formed in the semiconductor substrate 51 below the gate electrode 54, an impurity diffusing layer 56a is formed via an LDD layer 55. On the other side of the channel region formed in the semiconductor substrate 51 below the gate electrode 54, an impurity diffusing layer 56c is formed via the device isolation region 52. Silicide layers 57a and 57c are formed on the impurity diffusing layers 56a and 56c, respectively. A silicide layer 57d is formed on the gate electrode 54.

The silicide layer 57a can be formed on the impurity diffusing layer 56a spacing from the sidewall 59. The silicide layer 57d can be formed in a contact region on the gate electrode 54 to avoid a region on the gate electrode 54 on the gate oxide film 53.

On the impurity diffusing layers 56a and 56c, contact electrodes 58a and 58c electrically connected to the impurity diffusing layers 56a and 56c via the silicide layers 57a and 57c, respectively, are formed. On the gate electrode 54, contact electrodes 58d electrically connected to the gate electrode 54 via the silicide layer 57d. are formed The contact electrodes 58a and 58c can be electrically connected to each other.

A conduction type of the impurity diffusing layer 56a can be set to the N type and a conduction type of the impurity diffusing layer 56c and the well formed in the semiconductor substrate 51 can be set to the P type. Alternatively, the conduction type of the impurity diffusing layer 56a can be set to the P type and the conduction type of the impurity diffusing layer 56c and the well formed in the semiconductor substrate 51 can be set to the N type.

When the configuration shown in FIGS. 5A and 5B are used as the MOS transistor of the fuse element 11 shown in FIG. 1, the program voltage VBP is applied to the impurity diffusing layers 56a and 56c in a state in which the potential of the gate electrode 54 is maintained at the low potential VSS. As a result, the gate oxide film 53 is destroyed.

By using the configuration shown in FIGS. 5A and 5B as the MOS transistor of the fuse element 11 shown in FIG. 1, it is possible to suppress metal atoms included in the silicide layers 57a, 57c, and 57d from intruding into the gate oxide film 53 while making it possible to reduce contact resistance. Further, it is possible to remove a region of one of a source and a drain of the MOS transistor. It is possible to suppress, while realizing a reduction in a cell area, the resistance of the current path of the fuse element 11 from fluctuating according to a state of the metal atoms included in the silicide layers 57a, 57c, and 57d.

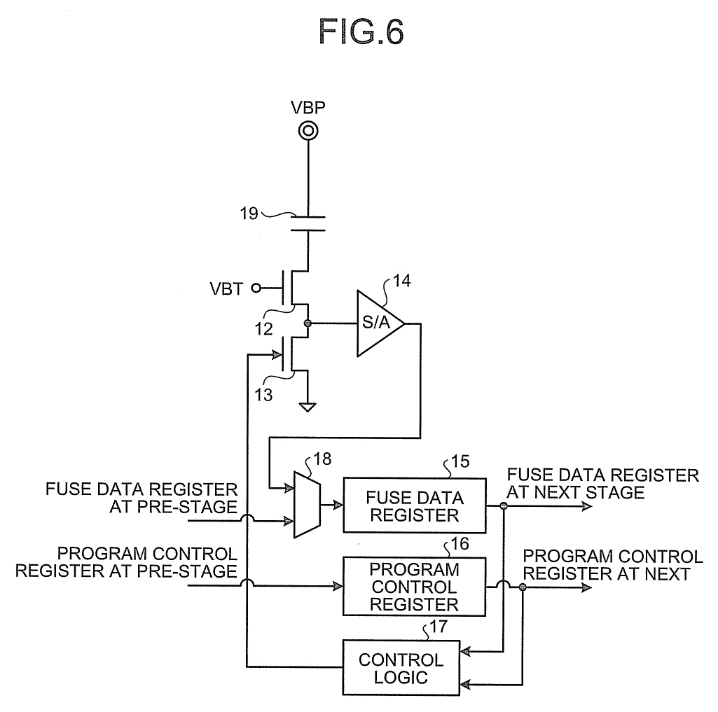

FIG. 6 is a block diagram of a schematic configuration of a nonvolatile semiconductor storage device according to a third embodiment of the present invention.

In FIG. 6, a fuse element 19 is provided in the nonvolatile semiconductor storage device instead of the fuse element 11 shown in FIG. 1. As the fuse element 19, a capacitor is used instead of the MOS transistor. In the capacitor, the gate oxide film of the MOS transistor can be formed as a capacitor insulating film and the gate electrode and the impurity diffusing layer of the MOS transistor can be formed as a capacitor electrode.

Because the capacitor is used as the fuse element 19 instead of the MOS transistor, it is unnecessary to form contact electrodes connected to a source layer and a drain layer of the MOS transistor. This makes it possible to reduce a cell area.

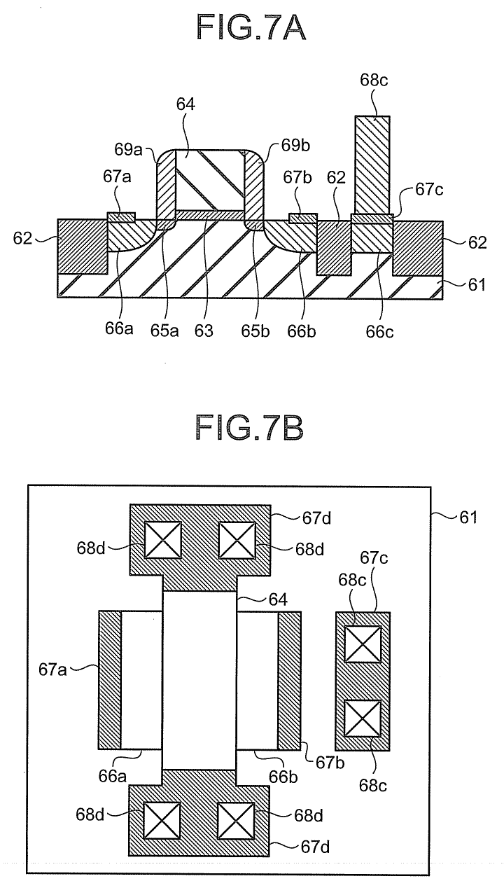

FIGS. 7A and 7B are a sectional view and a plan view of a schematic configuration of the fuse element 19 used in the nonvolatile semiconductor storage device shown in FIG. 6.

In FIGS. 7A and 7B, a device isolation region 62 is formed in a semiconductor substrate 61 in which a well is formed. In an active region on the semiconductor substrate 61 isolated by the device isolation regions 62, a gate electrode 64 is formed via a gate oxide film 63. Sidewalls 69a and 69b are formed on sides of the gate electrode 64.

On both sides of a channel region formed in the semiconductor substrate 61 below the gate electrode 64, impurity diffusing layers 66a and 66b are formed via LDD layers 65a and 65b, respectively. Beside the impurity diffusing layer 66b, an impurity diffusing layer 66c is formed via the device isolation region 62. Silicide layers 67a to 67c are formed on the impurity diffusing layers 66a to 66c, respectively. A silicide layer 67d is formed on the gate electrode 64.

The silicide layers 67a and 67b can be formed on the impurity diffusing layers 66a and 66b spacing from the sidewalls 69a and 69b, respectively. The silicide layer 67d can be formed in a contact region on the gate electrode 64 to avoid a region on the gate electrode 64 on the gate oxide film 63.

On the impurity diffusing layer 66c, contact electrodes 68c electrically connected to the impurity diffusing layer 66c via the silicide layer 67c are formed. On the gate electrode 64, contact electrodes 68d electrically connected to the gate electrode 64 via the silicide layer 67d are formed.

A conduction type of the impurity diffusing layers 66a to 66c and a conduction type of the well formed in the semiconductor substrate 61 can be set equal to each other. For example, the conduction type of the impurity diffusing layers 66a 66c and the conduction type of the well formed in the semiconductor substrate 61 can be set to the P type. Alternatively, the conduction type of the impurity diffusing layers 66a 66c and the conduction type of the well formed in the semiconductor substrate 61 can be set to the N type.

When the configuration shown in FIGS. 7A and 7B are used as the capacitor of the fuse element 19 shown in FIG. 6, the program voltage VBP is applied to the impurity diffusing layers 66a to 66c in a state in which the potential of the gate electrode 64 is maintained at the low potential VSS. As a result, the gate oxide film 63 is destroyed.

In the fuse element 19 shown in FIG. 6, by using the configuration shown in FIGS. 6A and 6B, it is possible to suppress metal atoms included in the silicide layers 67a to 67d from intruding into the gate oxide film 63 while making it possible to reduce contact resistance. Further, it is possible to make the contact electrode on the impurity diffusing layers 66a and 66b unnecessary. It is possible to suppress the resistance of a current path of the fuse element 19 from fluctuating according to a state of the metal atoms included in the silicide layers 67a to 67d.

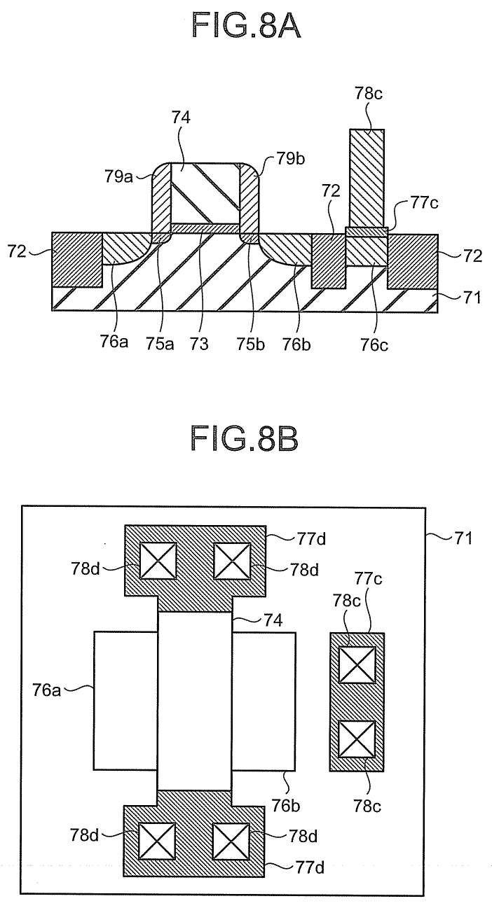

FIGS. 8A and 8B are a sectional view and a plan view of a schematic configuration of a fuse element used in a nonvolatile semiconductor storage device according to a fourth embodiment of the present invention.

In FIGS. 8A and 8B, a device isolation region 72 is formed in a semiconductor substrate 71 in which a well is formed. In an active region on the semiconductor substrate 71 isolated by the device isolation region 72, a gate electrode 74 is formed via a gate oxide film 73. Sidewalls 79a and 79b are formed on sides of the gate electrode 74.

On both sides of a channel region formed in the semiconductor substrate 71 below the gate electrode 74, impurity diffusing layers 76a and 76b are formed via LDD layers 75a and 75b, respectively. Beside the impurity diffusing layer 76b, an impurity diffusing layer 76c is formed via the device isolation region 72. A silicide layer 77c is formed on the impurity diffusing layer 76c. A silicide layer 77d is formed on the gate electrode 74. The silicide layer 77d can be formed on a contact region on the gate electrode 74 to avoid a region on the gate electrode 74 on the gate oxide film 73.

On the impurity diffusing layer 76c, contact electrodes 78c electrically connected to the impurity diffusing layer 66c via the silicide layer 77c. are formed On the gate electrode 74, contact electrodes 78d electrically connected to the gate electrode 74 via the silicide layer 77d are formed.

A conduction type of the impurity diffusing layers 76a to 76c and a conduction type of the well formed in the semiconductor substrate 71 can be set in common to the P type. Alternatively, the conduction type of the impurity diffusing layers 76a to 76c and the conduction type of the well formed in the semiconductor substrate 71 can be set in common to the N type.

When the configuration shown in FIGS. 8A and 8B are used as the capacitor of the fuse element 19 shown in FIG. 6, the program voltage VBP is applied to the impurity diffusing layers 76a to 76c in a state in which the potential of the gate electrode 74 is maintained at the low potential VSS. As a result, the gate oxide film 73 is destroyed.

In the fuse element 19 shown in FIG. 6, by using the configuration shown in FIGS. 8A and 8B, it is possible to suppress metal atoms included in the silicide layers 77c and 77d from intruding into the gate oxide film 73 while making it possible to reduce contact resistance. Further, it is possible to make the silicide layer and the contact electrode on the impurity diffusing layers 76a and 76b unnecessary. It is possible to suppress the resistance of the current path of the fuse element 19 from fluctuating according to a state of the metal atoms included in the silicide layers 77c and 77d.

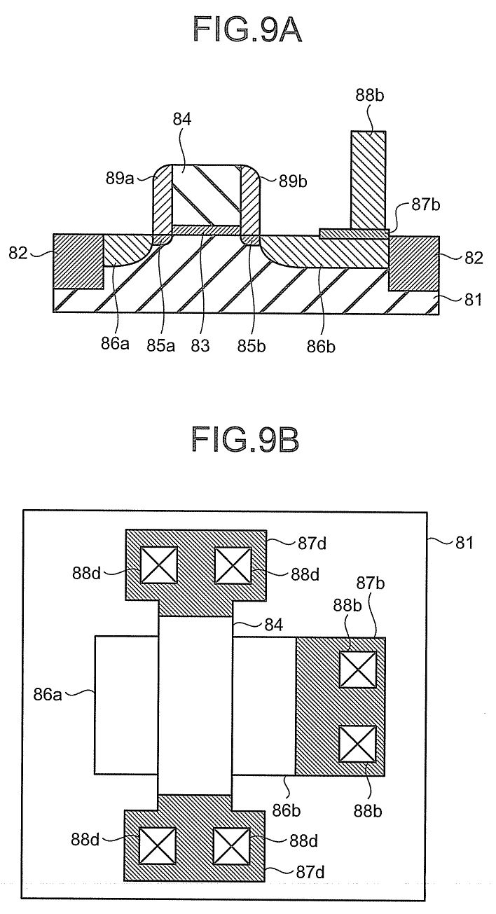

FIGS. 9A and 9B are a sectional view and a plan view of a schematic configuration of a fuse element used in a nonvolatile semiconductor storage device according to a fifth embodiment of the present invention.

In FIGS. 9A and 9B, a device isolation region 82 is formed in a semiconductor substrate 81 in which a well is formed. In an active region on the semiconductor substrate 81 isolated by the device isolation region 82, a gate electrode 84 is formed via a gate oxide film 83. Sidewalls 89a and 89b are formed on sides of the gate electrode 84.

On both sides of a channel region formed in the semiconductor substrate 81 below the gate electrode 84, impurity diffusing layers 86a and 86b are formed via LDD layers 85a and 85b, respectively. A silicide layer 87b is formed on the impurity diffusing layer 86b. A silicide layer 87d is formed on the gate electrode 84. The silicide layer 87d can be formed on a contact region on the gate electrode 84 to avoid a region on the gate electrode 84 of the gate oxide film 83.

On the impurity diffusing layer 86b, contact electrodes 88b electrically connected to the impurity diffusing layer 86b via the silicide layer 87b are formed. On the gate electrode 84, contact electrodes 88d electrically connected to the gate electrode 84 via the silicide layer 87d are formed.

A conduction type of the impurity diffusing layers 86a and 86b and a conduction type of the well formed in the semiconductor substrate 81 can be set in common to the P type. Alternatively, the conduction type of the impurity diffusing layers 86a and 86b and the conduction type of the well formed in the semiconductor substrate 81 can be set in common to the N type.

When the configuration shown in FIGS. 9A and 9B are used as the capacitor of the fuse element 19 shown in FIG. 6, the program voltage VBP is applied to the impurity diffusing layers 86a and 86b in a state in which the potential of the gate electrode 84 is maintained at the low potential VSS. As a result, the gate oxide film 83 is destroyed.

In the fuse element 19 shown in FIG. 6, by using the configuration shown in FIGS. 9A and 9B, it is possible to suppress metal atoms included in the silicide layers 87b and 87d from intruding into the gate oxide film 83 while making it possible to reduce contact resistance. Further, it is unnecessary to separately provide an impurity diffusing layer connected to the well formed in the semiconductor substrate 81. It is possible to suppress the resistance of the current path of the fuse element 19 from fluctuating according to a state of the metal atoms included in the silicide layers 87b and 87d.

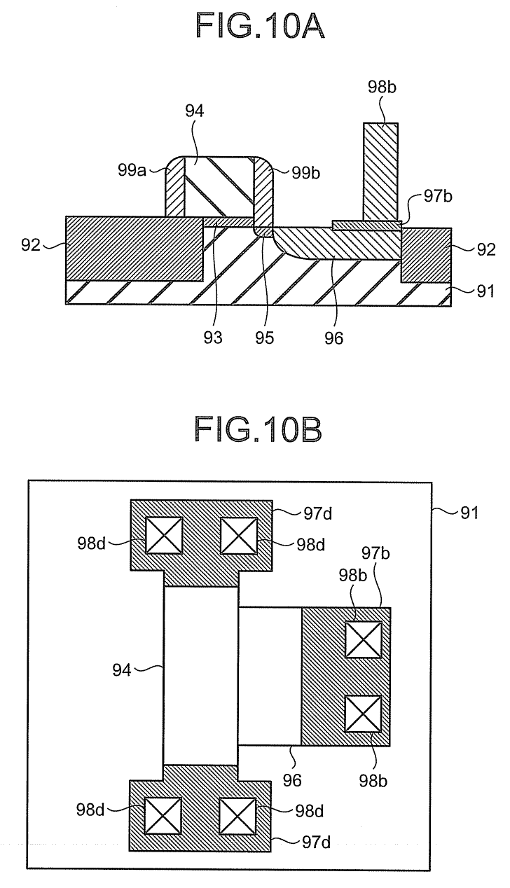

FIGS. 10A and 10B are a sectional view and a plan view of a schematic configuration of a fuse element used in a nonvolatile semiconductor storage device according to a sixth embodiment of the present invention.

In FIGS. 10A and 10B, a device isolation region 92 is formed in a semiconductor substrate 91 in which a well is formed. In an active region on the semiconductor substrate 91 isolated by the device isolation regions 92, a gate electrode 94 is formed via a gate oxide film 93. Sidewalls 99a and 99b are formed on sides of the gate electrode 94. One sidewall of the gate electrode 94 is aligned to extend over the device isolation region 92.

On one side of a channel region formed in the semiconductor substrate 91 below the gate electrode 94, the device isolation region 92 is aligned. On the other side of the channel region formed in the semiconductor substrate 91 below the gate electrode 94, an impurity diffusing layer 96 is formed via an LDD layer 95. A silicide layer 97b is formed on the impurity diffusing layer 96 spacing from the sidewall 99b. A silicide layer 97d is formed on the gate electrode 94. The silicide layer 97d can be formed in a contact region on the gate electrode 94 to avoid a region on the gate electrode 94 on the gate oxide film 93.

On the impurity diffusing layer 96, contact electrodes 98b electrically connected to the impurity diffusing layer 96 via the silicide layer 97b are formed. On the gate electrode 94, contact electrodes 98d electrically connected to the gate electrode 94 via the silicide layer 97d are formed.

A conduction type of the impurity diffusing layer 96 and a conduction type of the well formed in the semiconductor substrate 91 can be set in common to the P type. Alternatively, the conduction type of the impurity diffusing layer 96 and the conduction type of the well formed in the semiconductor substrate 91 can be set in common to the N type.

When the configuration shown in FIGS. 10A and 10B are used as the capacitor of the fuse element 19 shown in FIG. 6, the program voltage VBP is applied to the impurity diffusing layer 96 in a state in which the potential of the gate electrode 94 is maintained at the low potential VSS. As a result, the gate oxide film 93 is destroyed.

In the fuse element 19 shown in FIG. 6, by using the configuration shown in FIGS. 10A and 10B, it is possible to suppress metal atoms included in the silicide layers 97b and 97d from intruding into the gate oxide film 93 while making it possible to reduce contact resistance. Further, it is unnecessary to form an impurity diffusing layer on one side of the gate electrode 94. It is possible to suppress the resistance of the current path of the fuse element 19 from fluctuating according to a state of the metal atoms included in the silicide layers 97b and 97d.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor storage device comprising:
a gate electrode formed on a semiconductor substrate via a gate oxide film;
an impurity diffusing layer formed on the semiconductor substrate to be aligned at least on one side of the gate electrode;
a silicide layer formed in at least a part on the impurity diffusing layer to avoid a region on the gate electrode on the gate oxide film; and
a logic circuit configured to destroy the gate oxide film by applying voltage between the gate electrode and the impurity diffusing layer.

2. The nonvolatile semiconductor storage device according to claim 1, wherein the silicide layer is formed in a contact region on the gate electrode to avoid the region on the gate electrode on the gate oxide film and is formed in a contact region on the impurity diffusing layer to avoid both sides of the gate electrode.

3. The nonvolatile semiconductor storage device according to claim 1, wherein
the impurity diffusing layer is formed only on one side of the gate electrode, and
the silicide layer is formed in a contact region on the gate electrode drawn out from the impurity diffusing layer to avoid the region on the gate electrode of a side of impurity diffusing layer and is formed in a contact region on the impurity diffusing layer.

4. The nonvolatile semiconductor storage device according to claim 1, further comprising a sidewall formed on a side of the gate electrode, wherein
the silicide layer is formed on the impurity diffusing layer spacing from the sidewall.

5. The nonvolatile semiconductor storage device according to claim 1, further comprising a device isolation region aligned to be opposed to the impurity diffusing layer, which is aligned on one side of the gate electrode, such that a sidewall of the gate electrode extends over the device isolation region.

6. The nonvolatile semiconductor storage device according to claim 1, wherein the gate oxide film is formed on a well having a conduction type same as that of the impurity diffusing layer.

7. The nonvolatile semiconductor storage device according to claim 6, wherein
the gate oxide film forms a capacitor insulating film, and
the gate electrode and the impurity diffusing layer form a capacitor electrode.

8. The nonvolatile semiconductor storage device according to claim 7, wherein
the impurity diffusing layer is formed on both sides of the gate electrodes, and
the silicide layer is not formed on the impurity diffusing layer.

9. The nonvolatile semiconductor storage device according to claim 8, wherein a contact electrode is not formed on the impurity diffusing layer.

10. The nonvolatile semiconductor storage device according to claim 7, wherein
the impurity diffusing layer is formed on both sides of the gate electrode, and
the silicide layer is formed only on one side on the impurity diffusing layer.

11. The nonvolatile semiconductor storage device according to claim 10, wherein a contact electrode is not formed on the other side on the impurity diffusing layer.

12. The nonvolatile semiconductor storage device according to claim 7, wherein
the impurity diffusing layer is formed only on one side of the gate electrode, and
the silicide layer is formed on the impurity diffusing layer.

13. The nonvolatile semiconductor storage device according to claim 12, further comprising a contact electrode formed on the silicide layer.

14. A nonvolatile semiconductor storage device comprising:
a fuse element including a MOS transistor;
an internal-potential generating circuit that applies voltage between a gate electrode and an impurity diffusing layer of the MOS transistor to destroy a gate oxide film of the MOS transistor;
a sense amplifier that reads out data stored in the fuse element;
a barrier transistor that protects the sense amplifier from the voltage for destroying the gate oxide film; and
a selection transistor that selects the fuse element in which the gate oxide film of the MOS transistor is destroyed, wherein
a silicide layer is formed on gate electrodes and impurity diffusing layers of the barrier transistor and the selection transistor and is not formed on the gate electrode and the impurity diffusing layer of the MOS transistor.

15. The nonvolatile semiconductor storage device according to claim 14, further comprising:
a fuse data register that stores data read out by the sense amplifier; and
a selector that selects data output from a fuse data register of a pre-stage or the data read out by the sense amplifier and outputs the selected data to the fuse data register of an own stage of the selector.

16. The nonvolatile semiconductor storage device according to claim 15, wherein the fuse data registers are serially connected to form a register chain.

17. A nonvolatile semiconductor storage device comprising:
a fuse element including a capacitor;
an internal-potential generating circuit that applies voltage between capacitor electrodes of the capacitor to destroy a capacitor insulating film of the capacitor;
a sense amplifier that reads out data stored in the fuse element;
a barrier transistor that protects the sense amplifier from the voltage for destroying the capacitor insulating film; and
a selection transistor that selects the fuse element in which the capacitor insulating film of the capacitor is destroyed, wherein
a silicide layer is formed on gate electrodes and impurity diffusing layers of the barrier transistor and the selection transistor and is not formed on the capacitor electrodes of the capacitor.

18. The nonvolatile semiconductor storage device according to claim 17, further comprising:
a fuse data register that stores data read out by the sense amplifier; and
a selector that selects data output from a fuse data register of a pre-stage or the data read out by the sense amplifier and outputs the selected data to the fuse data register of an own stage of the selector.

19. The nonvolatile semiconductor storage device according to claim 18, wherein the fuse data registers are serially connected to form a register chain.

20. The nonvolatile semiconductor storage device according to claim 17, wherein
the capacitor insulating film is formed by a gate insulating film of a MOS transistor, and
the capacitor electrodes are formed by a gate electrode and an impurity diffusing layer of the MOS transistor.
